(19) United States
(12) Patent Application Publication
(10) Pub. No.: US 2025/0254945 A1
(43) Pub. Date: Aug. 7, 2025

(54) DIFFERENT DEPTH BACKSIDE S/D CONTACT PLACEHOLDER STRUCTURES

(71) Applicant: International Business Machines Corporation, Armonk, NY (US)

(72) Inventors: Tsung-Sheng Kang, Ballston Lake, NY (US); Tao Li, Slingerlands, NY (US); Ruilong Xie, Niskayuna, NY (US); Shogo Mochizuki, Mechanicville, NY (US)

(21) Appl. No.: 18/429,974

(22) Filed: Feb. 1, 2024

(51) Int. Cl. H01L 29/08; H01L 23/528; H01L 27/088; H01L 29/06; H01L 29/417; H01L 29/423; H01L 29/66; H01L 29/775; H01L 29/786

(52) U.S. Cl. CPC H10D 62/151; H01L 23/5286; H10D 30/014; H10D 30/43; H10D 30/6735; H10D 30/6757; H10D 62/118; H10D 64/017; H10D 64/258; H10D 84/83

(57) ABSTRACT

A semiconductor structure is provided that includes backside S/D contact placeholder structures that have different depths. Notably, a semiconductor structure is provided that includes a deep backside S/D contact placeholder structure for high-density devices having short channel lengths and a narrow space between each of the high-density devices, and a shallow backside S/D contact placeholder structure for high-performance devices having long channel lengths and a wide space between each of the high-performance devices.

### BACKGROUND

The present application relates to semiconductor technology, and more particularly to a semiconductor structure including a high-density device with deep backside source/drain (S/D) contact placeholder structures and a high-performance device with shallow backside S/D contact placeholder structures.

Over the last 30 years or so, the dimensions of semiconductor field effect transistors (FETS) have been steadily shrinking as scaling to smaller dimensions can lead to continuing device improvements. Planar FETs typically include a conducting gate electrode located over a semiconductor channel and electrically isolated from the channel by a gate dielectric layer. Current through the channel is controlled by applying voltage to the conducting gate. With conventional planar FET scaling reaching fundamental limits, the semiconductor industry is looking at more non-planar FET geometries that will facilitate continued device performance improvements. Examples of such non-planar FET geometries include FinFETs or nanosheet transistors.

### SUMMARY

A semiconductor structure is provided that includes backside S/D contact placeholder structures that have different depths. Notably, a semiconductor structure is provided that includes a deep backside S/D contact placeholder structure for high-density devices having short channel lengths and a narrow space between each of the high-density devices, and a shallow backside S/D contact placeholder structure for high-performance devices having long channel lengths and a wide space between each of the high-performance devices. The different depth backside S/D contact placeholder structures enable uniform S/D regions for the high-density devices and the high-performance devices.

In one aspect of the present application, a semiconductor structure is provided. In one embodiment of the present application, the semiconductor structure includes a first transistor having a first channel length and including a first gate structure and a first source/drain region located on each side of the first gate structure. The semiconductor structure further includes a first backside source/drain contact placeholder structure of a first depth located beneath, and in contact with, one of the first source/drain regions of the first transistor. The semiconductor structure even further includes a second transistor having a second channel length that is greater than the first channel length and including a second gate structure and a second source/drain region located on each side of the second gate structure. The semiconductor structure yet further includes a second backside source/drain contact placeholder structure of a second depth located beneath, and in contact with, one of the second source/drain regions of the second transistor, wherein the second depth is less than the first depth.

In another embodiment of the present application, the semiconductor structure includes a first transistor having a first channel length and including a first gate structure and a first source/drain region located on each side of the first gate structure. The semiconductor structure further includes a first backside source/drain contact placeholder structure of a first depth located beneath, and in contact with, one of the first source/drain regions of the first transistor. The semiconductor structure even further includes a second transistor having a second channel length that is greater than the first channel length and including a second gate structure and a second source/drain region located on each side of the second gate structure. The semiconductor structure yet further includes a second backside source/drain contact placeholder structure of a second depth located beneath, and in contact with, one of the second source/drain regions of the second transistor, wherein the second depth is less than the first depth, the first backside source/drain contact structure has a first backside source/drain contact placeholder structure width, and the second backside source/drain contact structure has a second backside source/drain contact placeholder structure width that is greater than the first backside source/drain contact structure width, and the first backside source/drain contact placeholder structure has a first volume and the second backside source/drain contact placeholder structure has a second volume, wherein the first volume is substantially equal to the second volume.

### BRIEF DESCRIPTION OF THE DRAWINGS

FIG. 1A is a top down view showing a high-density device layout that can be employed in the present application; the high-density device layout includes a plurality of active areas oriented along a first direction, and a plurality of gate structures that are oriented in a second direction which is perpendicular to the first direction; in the drawing cut X1-X1 is shown.

FIG. 1B is a top down view showing a high-performance device layout that can be employed in present application; the high-performance device layout includes a plurality of active areas oriented along a first direction, and a plurality of gate structures that are oriented in a second direction which is perpendicular to the first direction; in the drawing cut X2-X2 is shown.

FIG. 2A is a cross sectional view of a first exemplary semiconductor structure through cut X1-X1 shown in FIG. 1A that can be employed in accordance with an embodiment of the present application, the first exemplary semiconductor structure includes a plurality of first sacrificial gate structures located on a substrate, each first sacrificial gate structure is present on a first nanosheet stack including alternating first sacrificial semiconductor material nanosheets and first semiconductor channel material nanosheets.

FIG. 2B is a cross sectional view of a second exemplary semiconductor structure through cut X2-X2 shown in FIG. 1B that can be employed in accordance with an embodiment of the present application, the second exemplary semiconductor structure includes a plurality of second sacrificial gate structures located on the substrate, each second sacrificial gate structure is located on a second nanosheet stack including alternating second sacrificial semiconductor material nanosheets and second semiconductor channel material nanosheets.

FIGS. 3A and 3B are cross sectional views of the exemplary first and second exemplary semiconductor structures shown in FIGS. 2A and 2B, respectively, after protecting the device area including the plurality of second sacrificial gate structures with a first block mask, forming a first protective liner in the device area including the plurality of second sacrificial gate structures, and forming first recessed regions having a first depth and a first recessed width into an upper portion of the substrate in the device area including the plurality of first sacrificial gate structures.

FIGS. 4A and 4B are cross sectional views of the exemplary first and second exemplary semiconductor structures shown in FIGS. 3A and 3B, respectively, after removing the first block mask, forming a second block mask protecting the device area including the plurality of first sacrificial gate structures, forming a second protective liner in the device area including the plurality of second sacrificial gate structures, and forming second recessed regions having a second depth that is shallower than the first depth and a second recessed width that is greater than the first recessed width into an upper portion of the substrate in the device area including the plurality of second sacrificial gate structures.

FIGS. 5A and 5B are cross sectional views of the exemplary first and second exemplary semiconductor structures shown in FIGS. 4A and 4B, respectively, after removing the second block mask, and forming a first backside source/drain contact placeholder structure in each of the first recessed regions, and a second backside source/drain contact placeholder structure in each of the second recessed regions.

FIGS. 6A and 6B are cross sectional views of the exemplary first and second exemplary semiconductor structures shown in FIGS. 5A and 5B, respectively, after removing the first protective liner and the second protective liner, and forming a first source/drain region on top of each of the first backside source/drain contact placeholder structures, and a second source/drain region on top of each of the second backside source/drain contact placeholder structures.

FIGS. 7A and 7B are cross sectional views of the exemplary first and second exemplary semiconductor structures shown in FIGS. 6A and 6B, respectively, after removing the first sacrificial gate structures and the second sacrificial gate structures to reveal each of the first nanosheet stacks and the second nanosheet stacks, respectively, removing the first sacrificial semiconductor material nanosheets and the second sacrificial semiconductor material nanosheets, forming a first gate structure wrapped around each of the suspended first semiconductor channel material nanosheets, and a second gate structure wrapped around each of the suspended second semiconductor channel material nanosheets, forming a middle-of-the-line (MOL) dielectric layer having a first frontside source/drain contact structure contacting one of the first source/drain regions, and a second frontside source/drain contact structure contacting one of the second source/drain regions, forming a frontside back-end-of-the-line (BEOL) interconnect structure and a carrier wafer.

FIGS. 8A and 8B are cross sectional views of the exemplary first and second exemplary semiconductor structures shown in FIGS. 7A and 7B, respectively, after removing the substrate to revel each first backside source/drain contact placeholder structure and each second backside source/drain contact placeholder structure.

FIGS. 9A and 9B are cross sectional views of the exemplary first and second exemplary semiconductor structures shown in FIGS. 8A and 8B, respectively, after forming a first backside interlayer dielectric (ILD) layer.

FIGS. 10A and 10B are cross sectional views of the exemplary first and second exemplary semiconductor structures shown in FIGS. 9A and 9B, respectively, after backside patterning to reveal the first backside source/drain contact placeholder structure that is located beneath the first source/drain region that is not in direct contact with the first frontside source/drain contact structure.

FIGS. 11A and 11B are cross sectional views of the exemplary first and second exemplary semiconductor structures shown in FIGS. 10A and 10B, respectively, after removing the revealed first backside source/drain contact placeholder structure and the first semiconductor buffer layer to reveal the first source/drain region that is not in direct contact with the first frontside source/drain contact structure.

FIGS. 12A and 12B are cross sectional views of the exemplary first and second exemplary semiconductor structures shown in FIGS. 11A and 11B, respectively, after forming a first backside source/drain contact structure in direct contact with the revealed the first source/drain region that is not in direct contact with the first frontside source/drain contact structure, a second backside ILD layer including a first backside power rail in direct contact with the first backside source/drain contact structure, and forming a backside interconnect structure.

FIG. 13 is a cross sectional view showing a portion of the second exemplary semiconductor structure shown in FIG. 12B processed to include a second backside source/drain contact structure having a first end electrically connected to one of the second source/drain regions and a second end that is electrically connected to a backside interconnect structure through a second backside power rail.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

When high-density devices and high-performance devices are co-integrated with each other, there is an issue regarding how to form backside S/D contact placeholder structures for these distinct types of devices. Currently, in order to accompany small gate structure space variations, the backside S/D contact placeholder structures are epitaxially grown in all directions to guarantee that a topmost surface of the semiconductor buffer layer used in forming the S/D regions are flush at a similar level below the bottom channel to guarantee S/D epi growth at all the channel regions. In the present application, different depth backside S/D contact placeholder structures are formed that enable uniform S/D regions for high-density devices and high-performance devices. This and other aspects of the present application will become more apparent by the accompanying drawings and details that follow.

In the present application, a semiconductor structure is described and illustrated as containing nanosheet transistors. A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain (or S/D) region. A nanosheet transistor is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. The gate structure includes a gate dielectric and a gate electrode. The gate structure wraps each of the spaced apart semiconductor channel material nanosheets.

Although the present application describes and illustrates a semiconductor structure including nanosheet transistors, the present application works with other types of non-planar transistors which can include, stacked nanosheet transistors, finFETs, nanowire transistors or any combination of such transistors including the nanosheet transistors described and illustrated herein.

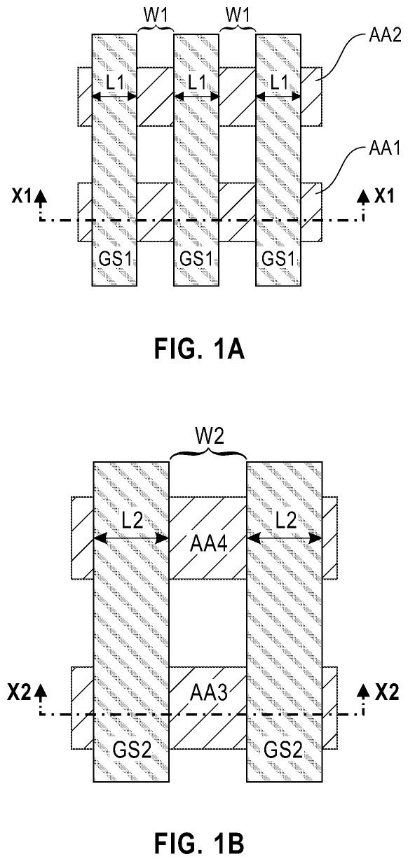

Referring first to FIG. 1A, there is illustrated a top down view showing a high-density device layout that can be employed in the present application. The illustrated high-density device layout includes a plurality of active areas, e.g., AA1 and AA2, oriented along a first direction, and a plurality of first gate structures, GS1, that are oriented in a second direction which is perpendicular to the first direction. Each of the first gate structures, GS1, runs parallel to each other. FIG. 1A includes a cut X1-X1 which runs through one of the active areas, e.g., AA1, and passes through each of the first gate structures, GS1, that are present in AA1. Each first gate structure, GS1, represents, a component of a first transistor of a high-density device. Each first transistor has a first channel length, L1, and adjacent first transistors are spaced apart by a gap having a first width, W1.

Referring now to FIG. 1B, there is illustrated a top down view showing a high-performance device layout that can be employed in present application. In the present application, the high-performance device layout is integrated on a same substrate as the high-density device layout.

The illustrated high-performance device layout includes a plurality of active areas, e.g., AA3 and AA4, oriented along a first direction, and a plurality of second gate structures, GS2, that are oriented in a second direction which is perpendicular to the first direction. Each of the second gate structures, GS2, runs parallel to each other. FIG. 1B includes a cut X2-X2 which runs through one of the active areas, e.g., AA3, and passes through each of the second gate structures, GS2, that are present in AA3. Each second gate structure, GS2, represents, a component of a second transistor of a high-performance device. Each second transistor has a second channel length, L2, and adjacent second transistors are spaced apart by a gap having a second width, W2. In the present application, the channel length is a measure of the distance between the source/drain regions that are located on each side of the gate structure. In the present application, the second channel length, L2, of each second transistor is greater than the first channel length, L1, of each first transistor. In the present application, the second width, W1, between adjacent second transistors is greater than the first width, W1, between adjacent first transistors. Thus and stated in different terms, each high-density transistor has a shorter channel length than each high-performance transistor, and the gap (or spacing) between each high-density transistor is narrower than the gap (or spacing) between each high-performance transistor.

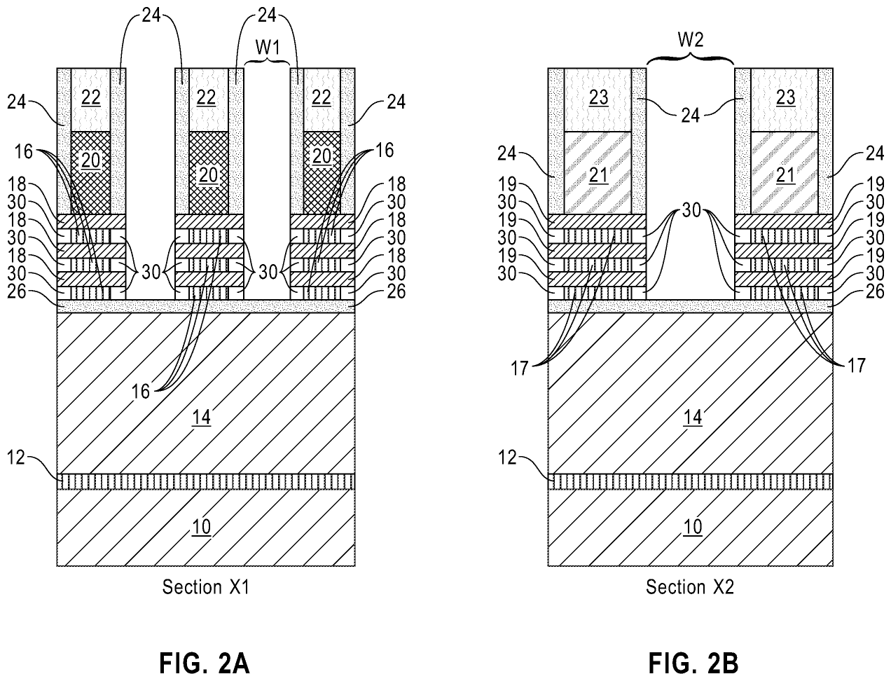

Referring now to FIG. 2A, there is illustrated a first exemplary semiconductor structure through cut X1-X1 shown in FIG. 1A that can be employed in accordance with an embodiment of the present application. The first exemplary semiconductor structure includes a plurality of first sacrificial gate structures 20 located on a substrate, each first sacrificial gate structure 20 is present on a first nanosheet stack including alternating first sacrificial semiconductor material nanosheets 16 and first semiconductor channel material nanosheets 18. The first exemplary structure also includes gate spacers 24 located along the sidewalls of each first sacrificial gate structure 20, a first optional hard mask cap 22 located on top of each first sacrificial gate structure 20, and inner spacers 30 located at opposing ends of each of the first sacrificial semiconductor material nanosheet 16. In the first exemplary semiconductor structure, a bottom dielectric isolation layer 26 is located on the substrate and beneath each of the first nanosheet stacks. As is illustrated in FIG. 2A, adjacent first sacrificial gate structures 20 are spaced apart from each other by a first width, W1.

Referring now to FIG. 2B, there is illustrated a second exemplary semiconductor structure through cut X2-X2 shown in FIG. 1B that can be employed in accordance with an embodiment of the present application. In the present application, the second exemplary structure and the first exemplary structure are located on the same substrate. As is illustrated in FIG. 2B, the second exemplary semiconductor structure includes a plurality of second sacrificial gate structures 21 located on the substrate, each second sacrificial gate structure 21 is located on a second nanosheet stack including alternating second sacrificial semiconductor material nanosheets 17 and second semiconductor channel material nanosheets 19. The second exemplary structure also includes gate spacers 24 located along the sidewalls of each second sacrificial gate structure 20, a second optional hard mask cap 23 located on top of each second sacrificial gate structure 21, and inner spacers 30 located at opposing ends of each of the second sacrificial gate structure 21. In the second exemplary semiconductor structure, the bottom dielectric isolation layer 26 is located on the substrate and beneath each of the second nanosheet stacks. As is illustrated in FIG. 2B, adjacent second sacrificial gate structures 21 are spaced apart from each other by a second width, W2, that is larger than W1. As can be observed from the drawings, the gate width of the first sacrificial gate structures 20 is smaller than gate width of the second sacrificial gate structures 21.

In the illustrated embodiment, the width of each first semiconductor channel material nanosheet 18 is equal to L1 mentioned above, and the width of each second semiconductor channel material nanosheet is equal to L2 mentioned above.

It is again emphasized that the first and second exemplary semiconductor structures illustrated in FIGS. 2A and 2B are integrated on a same substrate. In some embodiments of the present application, the substrate that includes the first and second exemplary semiconductor structure illustrated in FIGS. 2A and 2B can include a first semiconductor layer 10, an etch stop layer 12, and a second semiconductor layer 14. In another embodiment, etch stop layer 12 can be omitted and the substrate can include the first semiconductor layer 10 and the second semiconductor layer 14. In other embodiments, the substrate can include one of the first semiconductor layer 10 or the second semiconductor layer 14.

In embodiments of the present application, the first semiconductor layer 10 is composed of a first semiconductor material, while the second semiconductor layer 14 is composed of a second semiconductor material. Throughout the present application, each semiconductor material that is employed has semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. In embodiments, the first semiconductor material that provides the first semiconductor layer 10 can be compositionally the same as, or compositionally different from, the second semiconductor material that provides the second semiconductor layer 14. In some embodiments, the etch stop layer 12 can be composed of a dielectric material such as, for example, silicon dioxide and/or boron nitride. In other embodiments, the etch stop layer 12 is composed of a third semiconductor material that is compositionally different from, the first semiconductor material that provides the first semiconductor layer 10 and the second semiconductor material that provides the second semiconductor layer 14. In one example, the first semiconductor layer 10 is composed of silicon, the etch stop layer 12 is composed of silicon dioxide, and the second semiconductor layer 14 is composed of silicon. In another example, the first semiconductor layer 10 is composed of silicon, the etch stop layer 12 is composed of silicon germanium, and the second semiconductor layer 14 is composed of silicon.

Each first nanosheet stack of alternating first sacrificial semiconductor material nanosheets 16 and first semiconductor channel material nanosheets 18 can include any number of first sacrificial semiconductor material nanosheets 16 and any number of first semiconductor channel material nanosheets 18 and is not limited to the number of first sacrificial semiconductor material nanosheets 16 and second semiconductor channel material nanosheets 18 illustrated in the drawings. Each first sacrificial semiconductor material nanosheet 16 is composed of a fourth semiconductor material and each first semiconductor channel material nanosheet 18 is composed of a fifth semiconductor material. In the present application, the fourth semiconductor material is compositionally different from, the fifth semiconductor material. The fourth and fifth semiconductor materials include one of the semiconductor materials mentioned above. In one example, the fourth semiconductor material that provides each first sacrificial semiconductor material nanosheet 16 is composed of a silicon germanium alloy having a germanium content from 20 atomic percent to 40 atomic percent, and the fifth semiconductor material that provides each first semiconductor channel material nanosheet 18 is composed of silicon.

Each second nanosheet stack of alternating second sacrificial semiconductor material nanosheets 17 and second semiconductor channel material nanosheets 19 can include any number of second sacrificial semiconductor material nanosheets 17 and any number of second semiconductor channel material nanosheets 19 and is not limited to the number of second sacrificial semiconductor material nanosheets 17 and second semiconductor channel material nanosheets 19 illustrated in the drawings. Each second sacrificial semiconductor material nanosheet 17 is composed of the fourth semiconductor material mentioned above, and each second semiconductor channel material nanosheet 19 is composed of a sixth semiconductor material. In the present application, the fourth semiconductor material is compositionally different from, the sixth semiconductor material and the sixth semiconductor material can be compositionally the same as, or compositionally different from, the fifth semiconductor material. The fourth and sixth semiconductor materials include one of the semiconductor materials mentioned above. In one example, the fourth semiconductor material that provides each second sacrificial semiconductor material nanosheet 17 is composed of a silicon germanium alloy having a germanium content from 20 atomic percent to 40 atomic percent, and the sixth semiconductor material that provides each second semiconductor channel material nanosheet 19 is composed of silicon.

Each first sacrificial gate structure 20 includes at least a first sacrificial gate material. In some embodiments, the first sacrificial gate structure 20 can also include a first sacrificial gate dielectric material. In such embodiments, the first sacrificial gate dielectric material would be located beneath the first sacrificial gate material. The optional first sacrificial gate dielectric material can be composed of a dielectric material such as, for example, silicon dioxide. The first sacrificial gate material can be composed of, for example, polysilicon, amorphous silicon, amorphous silicon germanium or amorphous germanium. In embodiments, optional first hard mask cap 22 is present on top of each first sacrificial gate structure 20. In other embodiments, the optional first hard mask cap 22 can be omitted. When present, the first hard mask cap 22 is composed of a first hard mask material such as, for example, silicon nitride or silicon oxynitride.

Each second sacrificial gate structure 21 includes at least a second sacrificial gate material and optionally a second sacrificial gate dielectric material. When present, the second sacrificial gate dielectric material would be located beneath the second sacrificial gate material. The optional second sacrificial gate dielectric material can be composed of one of the dielectric materials mentioned above for the optional first sacrificial gate dielectric material. In the present application, the dielectric material that provides the optional first sacrificial gate dielectric material can be compositionally the same as, or compositionally different from, the optional second sacrificial gate dielectric material. The second sacrificial gate material can be composed of one of the materials mentioned above for the first sacrificial gate material. In the present application, the material that provides first sacrificial gate material can be compositionally the same as, or compositionally different from, the second sacrificial gate material. In embodiments, optional second hard mask cap 23 is present on top of each second sacrificial gate structure 21. In other embodiments, the optional second hard mask cap 23 can be omitted. When present, the second hard mask cap 22 is composed of a second hard mask material such as, for example, silicon nitride or silicon oxynitride. The second hard mask material can be compositionally the same as, or compositionally different from, the first hard mask material.

The gate spacers 24, the inner spacers 30 and the bottom dielectric isolation layer 26 are all composed of a spacer dielectric material. Typically, the gate spacers 24 and the bottom dielectric isolation layer 26 are composed of a compositionally same spacer dielectric material since they are oftentimes formed simultaneously. Illustrative examples of spacer dielectric materials that can be employed in the present application include, but are not limited to, silicon dioxide, SiN, SiBCN, SiOCN or SiOC.

The exemplary first and second semiconductor structures illustrated in FIGS. 2A and 2B can be formed utilizing any well-known nanosheet transistor device formation process. In the formation process, block mask technology can be used to process at least a portion of one of the exemplary semiconductor structures prior to the other. So as not to obscure any aspect of the method of the present application, the details regarding the formation of the exemplary first and second semiconductor structures illustrated in FIGS. 2A and 2B are not provided herein.

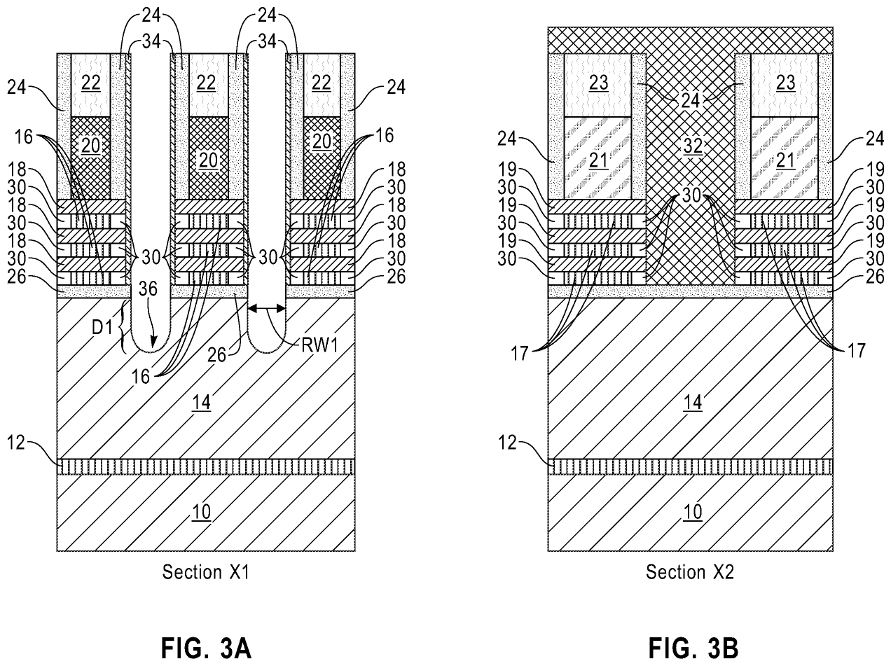

Referring now to FIGS. 3A and 3B, there are illustrated the exemplary first and second exemplary semiconductor structures shown in FIGS. 2A and 2B, respectively, after protecting the device area including the plurality of second sacrificial gate structures 21 with a first block mask 32, forming a first protective liner 34 in the device area including the plurality of first sacrificial gate structures 20, and forming first recessed regions 36 having a first depth, D1, and a first recessed width, RW1, into an upper portion of the substrate in the device area including the plurality of first sacrificial gate structures 20.

The protecting the device area including the plurality of second sacrificial gate structures 21 with the first block mask 32 includes forming a layer of a first block mask material in both device areas, and then lithographically patterning the layer of first block mask material to form the first block mask 32 protecting the device area including the plurality of second sacrificial gate structures 21. In some embodiments, the first block mask material can be composed of an organic planarization material. Since the first block mask 32 is present in only the device area including the plurality of second sacrificial gate structures 21, the device area including the plurality of first sacrificial gate structures 20 is physically exposed.

After first block mask 32 formation, the first protective liner 34 is formed. In embodiments of the present application, the first protective liner 34 is formed along sidewalls of the gate spacers 24, the first semiconductor channel material nanosheets 18 and the inner spacers 30. The first protective liner 34 is composed of a first sacrificial material that is compositionally different from, the first hard mask material and/or the first sacrificial gate material. Examples of first sacrificial materials that can be used in providing the first sacrificial liner 34 include, but are not limited to, a dielectric oxide or a dielectric nitride. The first sacrificial liner 34 can be formed by a deposition process such as, for example, chemical vapor deposition (CVD), plasma enhanced chemical vapor deposition (PECVD), or atomic layer deposition (ALD), followed by a directional etching process that removes the first sacrificial material from all horizontal surfaces of the device area including the plurality of first sacrificial gate structures 20.

Next, the first recessed regions 36 having the first depth, D1, and the first recessed width, RW1, are formed into an upper portion of the substrate (in the illustrated embodiment the first recessed regions 36 are formed into an upper portion of the second semiconductor layer 14) in the device area including the plurality of first sacrificial gate structures 20. The first recessed regions 36 are formed by an etching process such as, for example, a reactive ion etching (RIE), that first punches through the physically exposed bottom dielectric isolation layer 26 that is present in the device area including the plurality of first sacrificial gate structures 20 and then removes an upper portion of the substrate. It is noted that the first protective liner 34 protects the first semiconductor channel material nanosheets 18 from being etched during the formation of the first recessed regions 36.

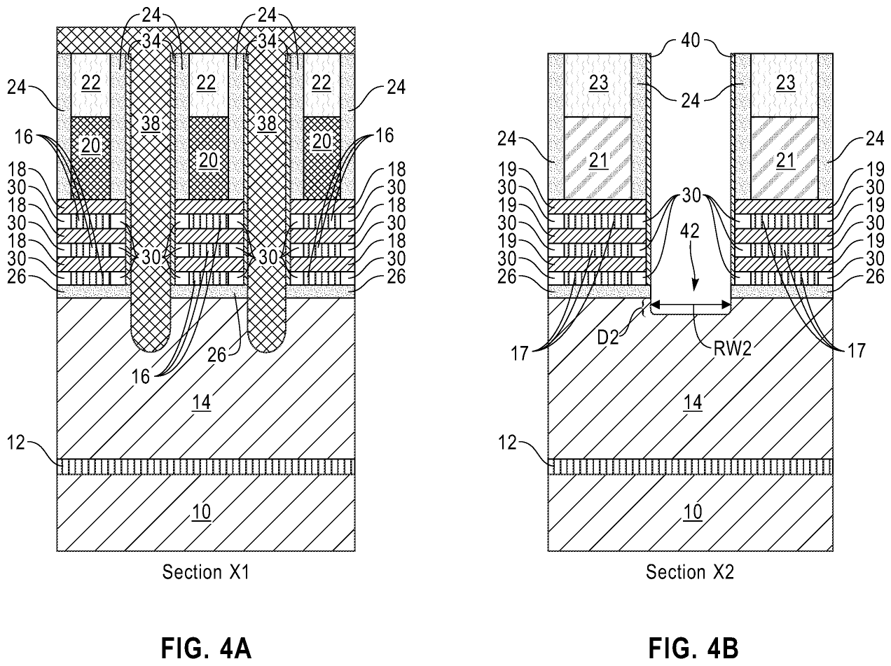

Referring now to FIGS. 4A and 4B, there are illustrated the exemplary first and second exemplary semiconductor structures shown in FIGS. 3A and 3B, respectively, after removing the first block mask 32, forming a second block mask 38 protecting the device area including the plurality of first sacrificial gate structures 20, forming a second protective liner 40 in the device area including the plurality of second sacrificial gate structures 21, and forming second recessed regions 42 having a second depth, D2, that is shallower than the first depth, D1, and a second recessed width, RW2, that is greater than the first recessed width, RW1, into an upper portion of the substrate in the device area including the plurality of second sacrificial gate structures 21.

The removal of the first block mask 32 includes any material removal process that is selective in removing the first sacrificial material that provides the first block mask 32. In one example, and when the first sacrificial material is an organic planarization material, the first block mask 32 can be removed by ashing.

The protecting the device area including the plurality of first sacrificial gate structures 20 with the second block mask 38 includes forming a layer of a second block mask material in both device areas, and then lithographically patterning the layer of second block mask material to form the second block mask 38 protecting the device area including the plurality of first sacrificial gate structures 20. In some embodiments, the second block mask material can be an organic planarization material. Since the second block mask 38 is present in only the device area including the plurality of first sacrificial gate structures 20, the device area including the plurality of second sacrificial gate structures 21 is physically exposed.

After second block mask 38 formation, the second protective liner 40 is formed. In embodiments of the present application, the second protective liner 40 is formed along sidewalls of the gate spacers 24, the second semiconductor channel material nanosheets 19 and the inner spacers 30. The second protective liner 40 is composed of a second sacrificial material that is compositionally different from, the first hard mask material and/or the second sacrificial gate material. The second sacrificial material can be compositionally the same as, or compositionally different from, the first sacrificial material. Examples of second sacrificial materials that can be used in providing the second sacrificial liner 40 include, but are not limited to, a dielectric oxide or a dielectric nitride. The second sacrificial liner 40 can be formed by a deposition process such as, for example, CVD, PECVD, or ALD, followed by a directional etching process that removes the second sacrificial material from all horizontal surfaces of the device area including the plurality of second sacrificial gate structures 21.

Next, the second recessed regions 42 having the second depth, D2, and the second recessed width, RW2, are formed into an upper portion of the substrate (in the illustrated embodiment the second recessed regions 42 are also formed into an upper portion of the second semiconductor layer 14) in the device area including the plurality of second sacrificial gate structures 21. The second recessed regions 42 are formed by an etching process such as, for example, a reactive ion etching (RIE), that first punches through the physically exposed bottom dielectric isolation layer 26 that is present in the device area including the plurality of second sacrificial gate structures 21 and then removes an upper portion of the substrate. It is noted that the second protective liner 40 protects the second semiconductor channel material nanosheets 19 from being etched during the formation of the second recessed regions 42.

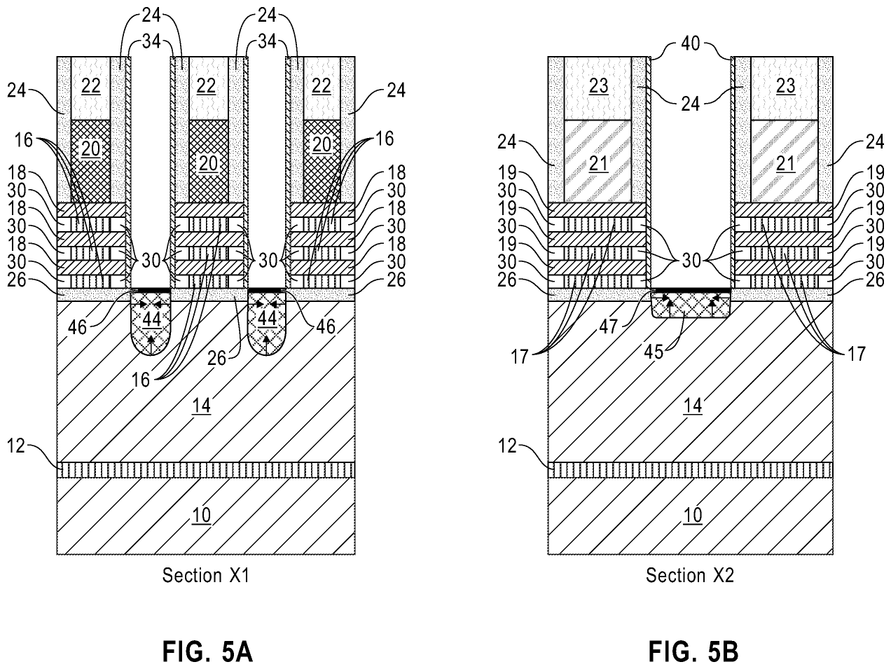

Referring now to FIGS. 5A and 5B, there are illustrated the exemplary first and second exemplary semiconductor structures shown in FIGS. 4A and 4B, respectively, after removing the second block mask 38, and forming a first backside source/drain contact placeholder structure 44 in each of the first recessed regions 36, and a second backside source/drain contact placeholder structure 45 in each of the second recessed regions 42. In some embodiment of the present application, and after formation of the first backside source/drain contact placeholder structure 44 and the second backside source/drain contact placeholder structure 45, a first semiconductor buffer layer 46 is formed on each of the first backside source/drain contact placeholder structure 44 and a second semiconductor buffer layer 47 is formed on each of the second backside source/drain contact placeholder structure 45.

The removal of the second block mask 38 includes any material removal process that is selective in removing the first sacrificial material that provides the second block mask 38. In one example, and when the second sacrificial material is an organic planarization material, the second block mask 38 can be removed by ashing.

The first backside source/drain contact placeholder structures 44 and the second backside source/drain contact placeholder structure 45 are composed of a same placeholder material. In one embodiment, the placeholder material is composed of a seventh semiconductor material. In one example, the seventh semiconductor material is composed of a silicon germanium alloy. The first backside source/drain contact placeholder structures 44 and the second backside source/drain contact placeholder structure 45 can be formed by deposition (e.g., CVD, PECVD or epitaxial growth) of the seventh semiconductor material, followed by a recess etch. The terms “epitaxial growth” or “epitaxially growing” means the growth of a semiconductor material on a growth surface of another semiconductor material, in which the semiconductor material being grown has the same crystalline characteristics as the growth surface of the another semiconductor material. In an epitaxial deposition process, the chemical reactants provided by the source gases are controlled and the system parameters are set so that the depositing atoms arrive at the growth surface of the another semiconductor material with sufficient energy to move around on the growth surface and orient themselves to the crystal arrangement of the atoms of the growth surface. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 550° C. to 900° C. Although higher temperature typically results in faster deposition, the faster deposition may result in crystal defects and film cracking.

In the present application, the first backside source/drain contact placeholder structures 44 and the second backside source/drain contact placeholder structure 45 grow up from a semiconductor sub-surface of the substrate and outward from the physically exposed sidewalls of the substrate. In the present application, the first backside source/drain contact placeholder structures 44 have the first depth, D1, and a first backside source/drain contact placeholder structure width that equals the first recessed width, RW1, and the second backside source/drain contact placeholder structure 45 has the second depth, D2, and a second backside source/drain contact placeholder structure width that is equal to the second recessed width, RW2. In the present application, D2 is at least 50% less than D1. In the present application, the second depth D2 should allow for the merging of the placeholder material that provides the second backside source/drain contact placeholder structure 45. Thus, and in the present application, the second backside source/drain contact placeholder structure width is greater than the first backside source/drain contact placeholder structure width. The first backside source/drain contact placeholder structures 44 and the second backside source/drain contact placeholder structure 45 have topmost surfaces that are substantially coplanar with a topmost surface of the substrate.

In some embodiments of the present application, the first backside source/drain contact placeholder structures 44 have a first volume and the second backside source/drain contact placeholder structure 45 has a second volume, wherein the first volume is substantially equal to the second volume.

The first semiconductor buffer layer 46 that can be optionally formed on each of the first backside source/drain contact placeholder structure 44 and the second semiconductor buffer layer 47 that can be optionally formed on each of the second backside source/drain contact placeholder structure 45 are composed of an eighth semiconductor material. The eighth semiconductor material is compositionally different from at least the seventh semiconductor material. The first semiconductor buffer layer 46 and the second semiconductor buffer layer 47 can be formed by a deposition process, followed by a recessed etch. The deposition process used in providing the first semiconductor buffer layer 46 and the second semiconductor buffer layer 47 is typically an epitaxial growth process as defined above. The semiconductor buffer layer 46 and the second semiconductor buffer layer 47 aid in the formation of the source/drain regions in each of the device areas. The first semiconductor buffer layer 46 and the second semiconductor buffer layer 47 have topmost surfaces that are substantially coplanar with a topmost surface of the bottom dielectric isolation layer 26.

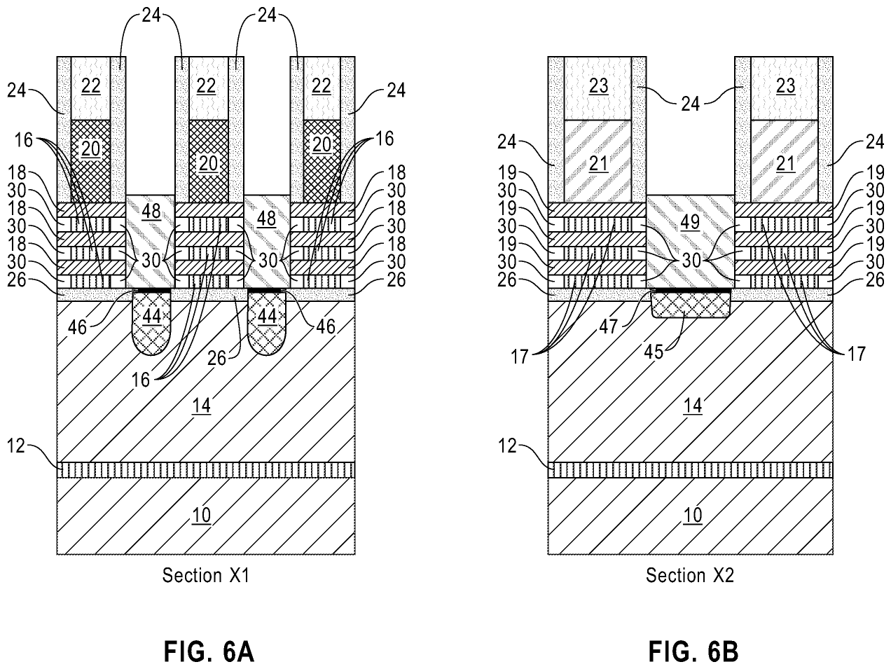

Referring now to FIGS. 6A and 6B, there are illustrated the exemplary first and second exemplary semiconductor structures shown in FIGS. 5A and 5B, respectively, after removing the first protective liner 34 and the second protective liner 40, and forming a first source/drain region 48 on top of each of the first backside source/drain contact placeholder structures 44, and a second source/drain region 49 on top of each of the second backside source/drain contact placeholder structures 45. It is noted that FIG. 6B only shows the formation of one of the second source/drain regions 49; the other second source/drain region 49 would be formed on the other side of the second sacrificial gate structures 21 shown in FIG. 6B.

The first protective liner 34 and the second protective liner 40 can be removed utilizing a single etching process (typically the case when the first protective liner 34 and the second protective liner 40 are composed of a compositionally same protective material) or more than one etching processes (typically the case when the first protective liner 34 and the second protective liner 40 are composed of compositionally different proactive materials).

The first source/drain regions 48 are composed of a ninth semiconductor material and a first dopant, and the second source/drain regions 49 are composed of a tenth semiconductor material and a second dopant. As used herein, a “source/drain” region can be a source region or a drain region depending on subsequent wiring and application of voltages during operation of the transistor. The ninth semiconductor material can be compositionally the same or compositionally different from, the trench semiconductor material. The ninth semiconductor material can be compositionally the same as, or compositionally different from, the fourth semiconductor material that provides each first semiconductor channel material nanosheet 18, and the tenth semiconductor material can be compositionally the same as, or compositionally different from, the fifth semiconductor material that provides each second semiconductor channel material nanosheet 19. The first dopant and the second dopant can be of a same conductivity type (i.e., an n-type dopant or a p-type dopant) or different conductivity types. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each source/drain region can have a dopant concentration of from 4×10²⁰ atoms/cm³ to 3×10²¹ atoms/cm³.

The first source/drain regions 48 and the second source/drain regions 49 can be formed utilizing an epitaxial growth process as defined herein. The dopant within the first source/drain regions 48 and the second source/drain regions 49 can be added in-situ during the epitaxial growth process, of following the epitaxial growth process utilizing any conventional dopant introduction process such as, for example, dopant ion implantation.

As is illustrated in the drawings, the first source/drain regions 48 have a narrower width than the second source/drain regions 49. In some embodiments, the first source/drain regions 48 can be formed directly on the first semiconductor buffer layer 46 and the second source/drain regions 49 can be formed directly on the second semiconductor buffer layer 47. In other embodiments, the first source/drain regions 48 can be formed directly on each of the first backside source/drain contact placeholder structures 44, and the second source/drain regions 49 can be formed directly on the each of the second backside source/drain contact placeholder structures 45.

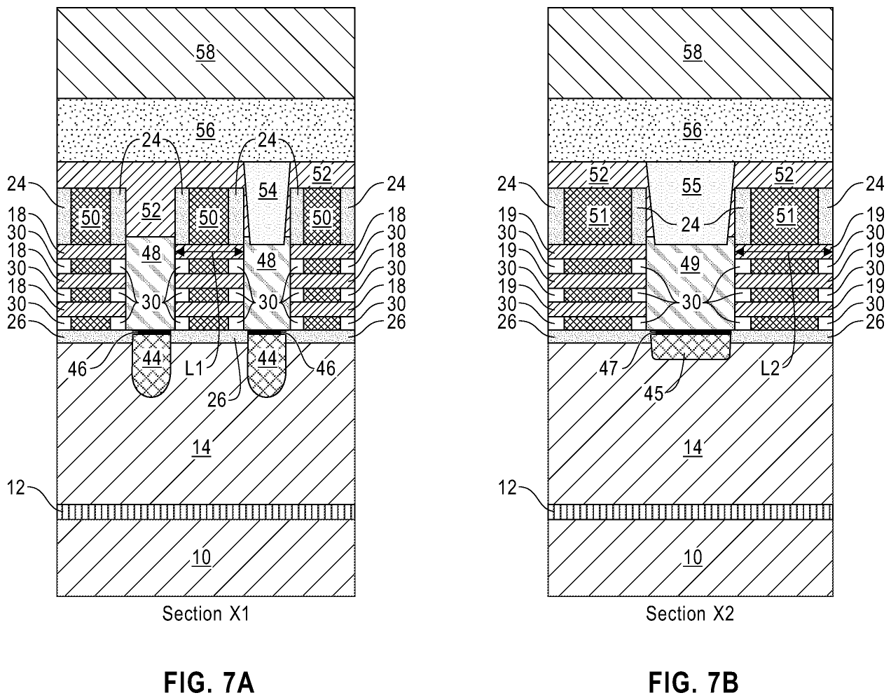

Referring now to FIGS. 7A and 7B, there are illustrated the exemplary first and second exemplary semiconductor structures shown in FIGS. 6A and 6B, respectively, after removing the first sacrificial gate structures 20 and the second sacrificial gate structures 21 to reveal each of the first nanosheet stacks and the second nanosheet stacks, respectively, removing the first sacrificial semiconductor material nanosheets 16 and the second sacrificial semiconductor material nanosheets 17, forming a first gate structure 50 wrapped around each of the suspended first semiconductor channel material nanosheets 18, and a second gate structure 51 wrapped around each of the suspended second semiconductor channel material nanosheets 19, forming a MOL dielectric layer 52 having a first frontside source/drain contact structure 54 contacting one of the first source/drain regions 48, and a second frontside source/drain contact structure 55 contacting one of the second source/drain regions 49, forming a frontside BEOL interconnect structure 56 and a carrier wafer 58.

It is noted that prior to removing the first sacrificial gate structures 20 and the second sacrificial gate structures 21, a first frontside interlayer dielectric (ILD) layer (not specifically shown) is formed on the first source/drain regions 48 and the second source/drain regions 49. The first ILD layer is composed of a dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer, or any combination thereof. The term “low-k” as used throughout the present application denotes a dielectric material that has a dielectric constant of less than 4.0 (all dielectric constants mentioned herein are relative to a vacuum unless otherwise noted). The first ILD layer can be formed by deposition (CVD, PECVD or spin-on coating), followed by a planarization process. The planarization process can remove an upper portion of the gate spacers 24 as well as the first hard mask cap 22 from on top of each of the first sacrificial gate structures 20 and the second hard mask cap 23 from on top of each of the second sacrificial gate structures 21.

Each first sacrificial gate structure 20 and each second sacrificial gate structure 21 can be removed from the structure utilizing one or more material removal processes such as, for example, etching, which is (are) selective in removing the first sacrificial gate structures 20 and the second sacrificial gate structures 21. The material removal of each first sacrificial gate structure 20 reveals each first nanosheet and the material removal of each second sacrificial gate structure 21 reveals each second nanosheet stack. After revealing the first and second nanosheet stacks, each first sacrificial semiconductor material nanosheet 16 and each second sacrificial semiconductor material nanosheet 17 is removed. The removal of the first sacrificial semiconductor material nanosheets 16 suspends a portion of each first semiconductor channel material nanosheet 18, while the removal of the second sacrificial semiconductor material nanosheets 17 suspends a portion of each second semiconductor channel material nanosheet 19. Each first sacrificial semiconductor material nanosheet 16 and each second sacrificial semiconductor material nanosheet 17 is removed utilizing any material removal process such as, for example, etching, which is selective in removing the respective sacrificial semiconductor material nanosheets.

As mentioned above, the first gate structure 50 wraps around each of the first semiconductor material nanosheets 18 of the first nanosheet stacks, and the second gate structure 51 wraps around each of the second semiconductor material nanosheets 19 of the second nanosheet stacks The first gate structure 50 includes a first gate dielectric layer and a first gate electrode; both the first gate dielectric layer and the first gate electrode are not separately shown in the drawing, but both are included in the area shown as the first gate structure 50. The second gate structure 51 includes a second gate dielectric layer and a second gate electrode; both the second gate dielectric layer and the second gate electrode are not separately shown in the drawing, but both are included in the area shown as the second gate structure 51. In the present application, the first gate dielectric material can be compositionally the same as, or compositionally different from, the second gate dielectric material. Also, and in the present application, the first gate electrode can be compositionally the same as, or compositionally different from, the second gate electrode.

As is known, the gate dielectric layer is formed directly around the suspended portion of each semiconductor channel material nanosheet and the gate electrode is formed on the gate dielectric layer. The gate dielectric material that can be used as the first and second gate dielectric material layers typically has a dielectric constant of greater than 4.0. Illustrative examples of gate dielectric materials that can be used in providing the first and second gate dielectric layers include, but are not limited to, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The gate dielectric material the first and second gate dielectric material layers can further include dopants such as lanthanum (La), aluminum (Al) and/or magnesium (Mg).

The gate electrode material that can be used in providing the first gate electrode and the second gate electrode can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations and thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co). The first and second gate structures can be formed by deposition of the gate dielectric material and the gate electrode material, followed by a planarization process.

Referring back to FIG. 7A, first transistors are present. Each first transistor includes the first gate structure 50 and first source/drain regions 48 located on each side of the first gate structure 50. Each first transistor has a first channel length, L1, and is spaced apart by first width, W1.

Referring back to FIG. 7B, second transistors are present. Each second transistor includes the second gate structure 51 and second source/drain regions 49 located on each side of the second gate structure 51. Each second transistor has a second channel length, L1, and is spaced apart by second width, W2. In the present application, L2 is greater than L1, and W2 is greater than W1.

After forming the first gate structure 50 and the second gate structure 51, a second frontside ILD layer (not specifically shown) is formed on the first frontside ILD layer and on top of the first gate structure 50 and the second gate structure 51. In the present application, the first frontside ILD layer and the second frontside ILD layer provide the MOL dielectric layer 52 shown in FIGS. 7A and 7B. The second frontside ILD layer includes one of the dielectric materials mentioned above for the first frontside ILD layer, and the second frontside ILD layer can be formed by deposition, followed by a planarization process.

The first frontside source/drain contact structure 54 and the second frontside source/drain contact structure 55 can be formed by a metallization process. The metallization process includes forming contact openings in the MOL dielectric layer 52 and then filling (including deposition and planarization) those contact openings with at least a contact conductor material. The contact conductor material that can be used for providing the frontside contact structures includes, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. The first frontside source/drain contact structure 54 and the second frontside source/drain contact structure 55 can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above.

In the present application, the first frontside source/drain contact structure 54 is formed in contact with one of the first source/drain regions 48 of a first transistor that includes one of the first gate structures 50, and the second frontside source/drain contact structure 55 is formed in contact with one of the second source/drain regions 49 of a second transistor that includes one of the second gate structures 51.

The frontside BEOL interconnect structure 56 can include one or more interconnect dielectric material layers (including one of the dielectric materials mentioned above for the first frontside ILD layer) that contain frontside metal wires (the metal wires can be composed of any electrically conductive metal or electrically conductive metal alloy) embedded therein. Electrical contact of the frontside BEOL interconnect structure 56 to both the first frontside source/drain contact structure 54 and the second frontside source/drain contact structure 55 is made.

The carrier wafer 58 can include one of the semiconductor materials mentioned above for the substrate. Carrier wafer 58 is bonded to the frontside BEOL interconnect structure 56 after frontside BEOL interconnect structure 56 formation. The carrier wafer 58 is used in backside processing and is typically removed from the structures after completing the backside processing.

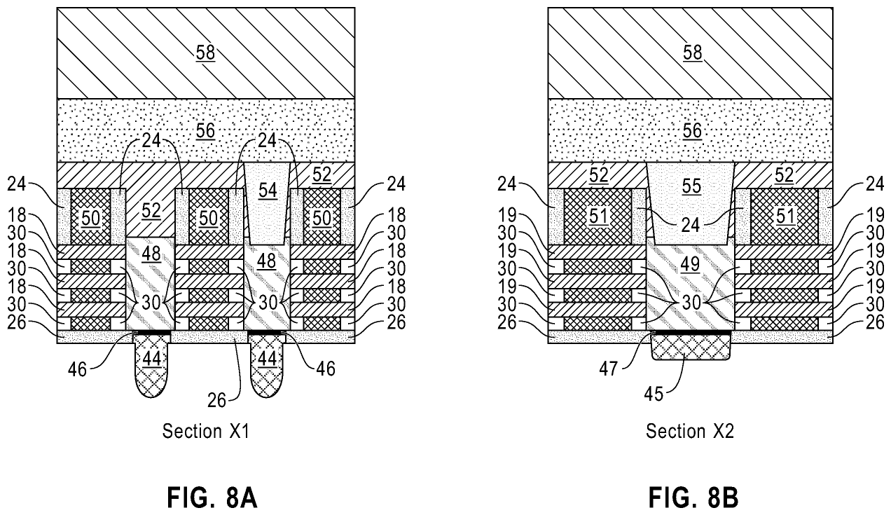

Referring now to FIGS. 8A and 8B, there are illustrated the exemplary first and second exemplary semiconductor structures shown in FIGS. 7A and 7B, respectively, after removing the substrate to revel each first backside source/drain contact placeholder structure 44 and each second backside source/drain contact placeholder structure 45. The removal of the substrate typically includes flipping the wafer 180° to physically expose a backside of the substrate. This flipping step is not shown in the drawings of the present application for clarity. The flipping physically exposes the substrate for backside processing. Flipping can be performed by hand or by utilizing a mechanical means such as, for example, a robot arm. In the illustrated embodiment, the removal of the physically exposed substrate can include one or more material removal process that is (are) selective in removing the substrate. In embodiments in which the substrate includes the first semiconductor layer 10, the etch stop layer 12 and the second semiconductor 14, three sperate material removal processes can be employed. In such an embodiment, the first removal process removes the first semiconductor layer 10 stopping on the etch stop layer 12. The second removal process removes the etch stop layer 12 stopping on the first semiconductor layer 14. The third removal process then removes the second semiconductor layer 14.

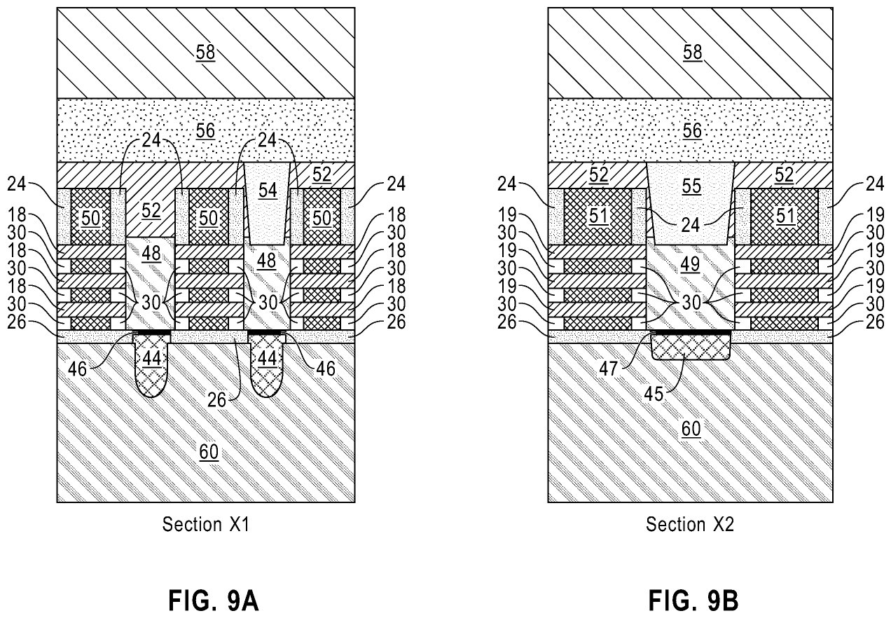

Referring now to FIGS. 9A and 9B, there are illustrated the exemplary first and second exemplary semiconductor structures shown in FIGS. 8A and 8B, respectively, after forming a first backside ILD layer 60. The first backside ILD layer 60 is composed of one of the dielectric materials mentioned above for the first frontside ILD layer. The first backside ILD layer 60 can be formed by a deposition process such as, for example, CVD, PECVD or spin-on coating. In the present application, the first backside ILD layer 60 embeds each first backside source/drain contact placeholder structure 44 and each second backside source/drain contact placeholder structure 45.

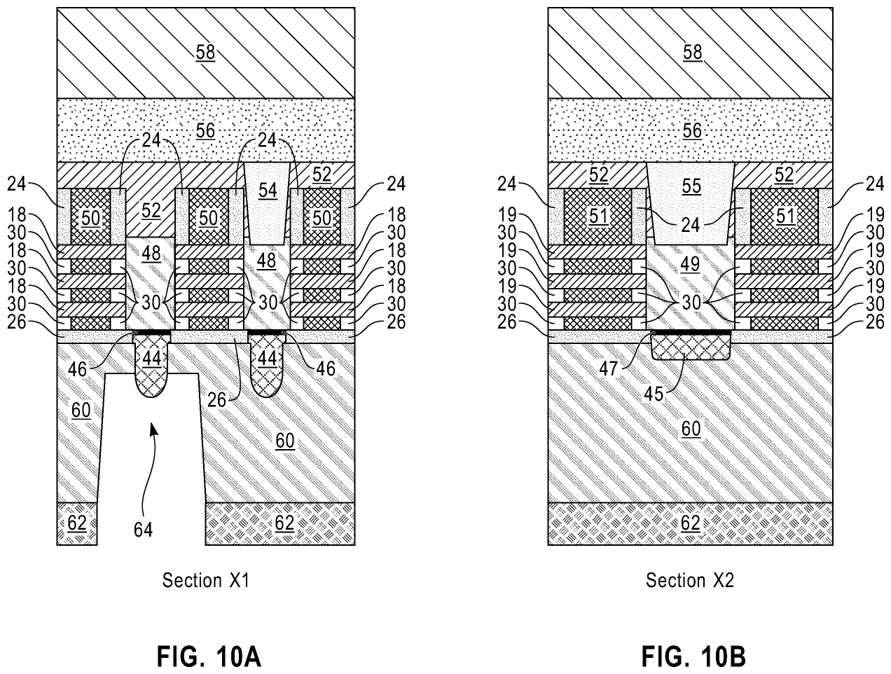

Referring now to FIGS. 10A and 10B, there are illustrated the exemplary first and second exemplary semiconductor structures shown in FIGS. 9A and 9B, respectively, after backside patterning to reveal the first backside source/drain contact placeholder structure 44 that is located beneath the first source/drain region 48 that is not in direct contact with the first frontside source/drain contact structure. The backside patterning includes forming a masking material layer 62 on the first backside ILD layer 60. The masking material layer 62 is composed of any masking material or combination of masking materials that are well known to those skilled in the art. In one example, the masking material layer 62 is composed of an organic planarization material. The masking material layer 62 can be formed utilizing a deposition process including, for example, CVD, PECVD or spin-on coating. The backside patterning continues by forming a backside opening 64 in the masking material layer 62 and the first backside ILD layer 60. The backside opening 64 is formed by lithography and etching. The backside opening 64 reveals the first backside source/drain contact placeholder structure 44 that is located beneath the first source/drain region 48 that is not in direct contact with the first frontside source/drain contact structure.

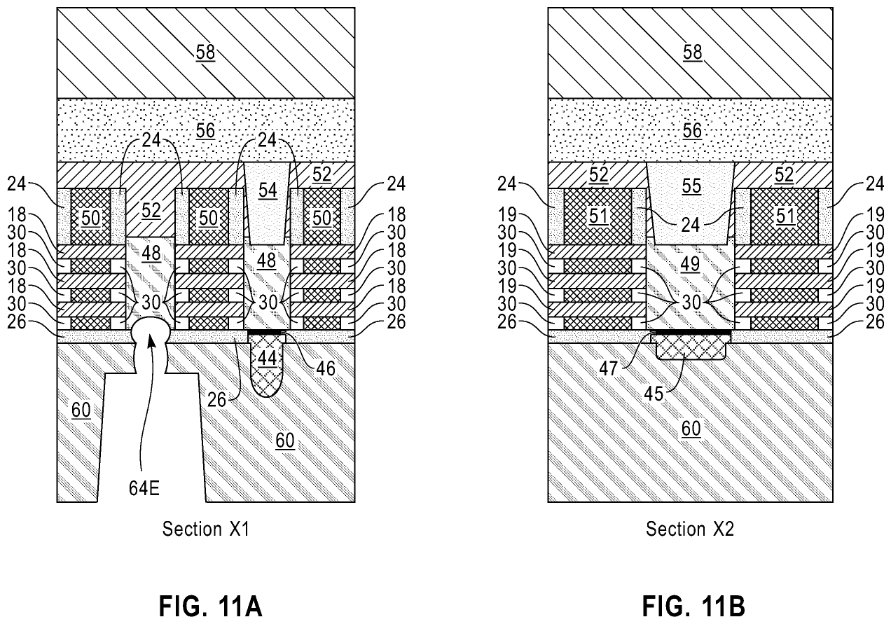

Referring now to FIGS. 11A and 11B, there are illustrated the exemplary first and second exemplary semiconductor structures shown in FIGS. 10A and 10B, respectively, after removing the revealed first backside source/drain contact placeholder structure 44 and the first semiconductor buffer layer 46 (if the same is present) to reveal the first source/drain region 48 that is not in direct contact with the first frontside source/drain contact structure 54. The removal of the first backside source/drain contact placeholder structure 44 and the first semiconductor buffer layer 46 (if the same is present) includes one or more material removal processes such as, for example, etching. The removal of the first backside source/drain contact placeholder structure 44 and the first semiconductor buffer layer 46 (if the same is present) provides an extended backside opening 64E that reveals the first source/drain region 48 that is not in direct contact with the first frontside source/drain contact structure 54. The masking material layer 62 is typically removed after forming the extended backside opening 64E utilizing a material removal process such as, for example, ashing, which is selective in removing the masking material layer 62.

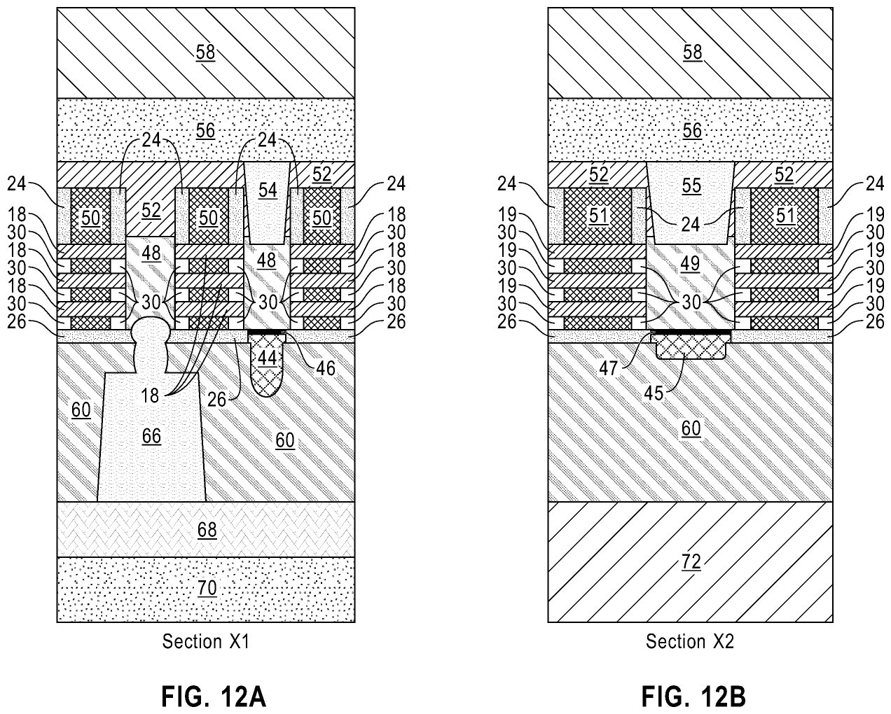

Referring now to FIGS. 12A and 12B, there are illustrated the exemplary first and second exemplary semiconductor structures shown in FIGS. 11A and 11B, respectively, after forming a first backside source/drain contact structure 66 in direct contact with the revealed the first source/drain region 48 that is not in direct contact with the first frontside source/drain contact structure 54, a second backside ILD layer 72 including a first backside power rail 68 in direct contact with the first backside source/drain contact structure 66, and forming a backside interconnect structure 70. In this embodiment, the backside interconnect structure 70 is formed only in the high-density device area as shown in FIG. 12A.

The first backside source/drain contact structure 66 can be formed by filling (including deposition and planarization) the extended backside opening with at least a contact conductor material, as defined above. The first backside source/drain contact structure 66 can also include one or more contact liners (not shown), as defined above. In one or more embodiments in which a contact liner is present, the contact liner (not shown) can include a silicide liner, such as Ti, Ni, NiPt, etc., and a diffusion barrier material, as defined above.

The second backside ILD layer 72 includes one of the dielectric materials mentioned above for the first frontside ILD layer. The second backside ILD layer 72 can be composed of a compositionally same, or compositionally different, dielectric material that the first backside ILD layer 60. The second backside ILD layer 72 can be formed by a deposition process such as, for example, CVD, PECVD or spin-on coating.

The first backside power rail 68 is composed of any electrically conductive power rail material including, but not limited to, tungsten (W), cobalt (Co), ruthenium (Ru), aluminum (Al), copper (Cu), platinum (Pt), rhodium (Rh), or palladium (Pd). A diffusion barrier, not shown, can be present on at least the sidewalls of the a first backside power rail 68. In some embodiments, the first backside power rail 68 can be formed utilizing a damascene process in which a backside power rail opening is formed in the second backside ILD layer 72 and backside power rail opening is then filled with at least one of the electrically conductive power rail materials mentioned above. The filling of the backside power rail opening an include a deposition process such as, for example, CVD, PECVD, ALD, sputtering or plating. A planarization process can follow the deposition process. In other embodiments, a substrative patterning process can be used in which the first backside power rail 68 is first formed by deposition of a layer of an electrically conductive power rail material, followed by patterning the deposited layer of electrically conductive power rail material into the first backside power rail 68. The second backside ILD 72 layer can then be formed to embed the first backside power rail 68.

The backside interconnect structure 70 includes ILD layers having backside metal wires (the metal wires can be composed of any electrically conductive metal or electrically conductive metal alloy) embedded therein In the present application, backside interconnect structure 70. can serve as a backside power distribution network, and it can be formed in contact with the first backside power rail 68.

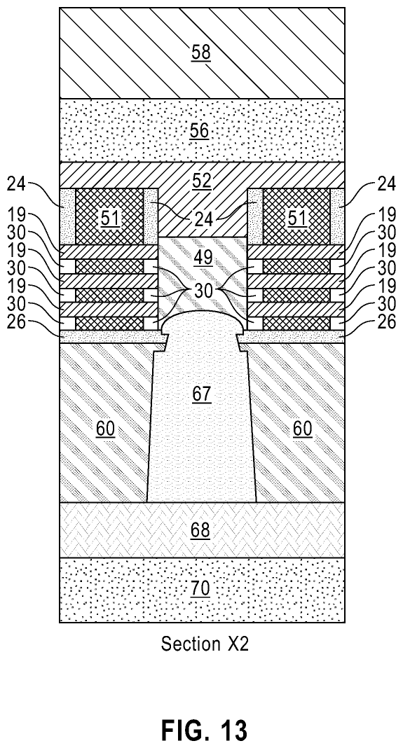

Referring now to FIG. 13, there is illustrated a portion of the second exemplary structure to the left hand side or the right hand side in FIG. 12B processed to include a second backside source/drain contact structure 67 having a first end electrically connected to one of the second source/drain regions 49 and a second end that is electrically connected to backside interconnect structure 70 through a second backside power rail 68. The second backside source/drain contact structure 67 can be formed utilizing the same processes and materials as mentioned above in forming the first backside source/drain contact structure 66. The second backside power rail 67 can be formed utilizing a damascene or subtractive patterning process as are mentioned above in forming the first backside power rail 66. The second backside power rail 67 can include one of the electrically conductive power rail materials mentioned above for the first backside power rail 66. The backside interconnect structure 70 for this embodiment is the same as defined above. Note that the backside interconnect structure 70 is typically continuous structure that is located beneath each of the different device areas.

FIGS. 12A, 12B and 13 illustrate semiconductor structures in accordance with the present application. The structures include a first transistor having first channel length, L1, and including first gate structure 50 and first source/drain region 48 located on each side of the first gate structure 50. The semiconductor structure further includes a first backside source/drain contact placeholder structure 44 of first depth, D1, located beneath, and in contact with, one of the first source/drain regions 48 of the first transistor. The semiconductor structure even further includes a second transistor having second channel length, L2, that is greater than the first channel length, L1, and including a second gate structure 51 and second source/drain region 49 located on each side of the second gate structure 51. The semiconductor structure yet further includes second backside source/drain contact placeholder structure 45 of the second depth, D2, located beneath, and in contact with, one of the second source/drain regions 49 of the second transistor, wherein the second depth, D2, is less than the first depth, D1.

In some embodiments, the first backside source/drain contact structure has a first backside source/drain contact placeholder structure width, and the second backside source/drain contact structure has a second backside source/drain contact placeholder structure width that is greater than the first backside source/drain contact structure width, and the first backside source/drain contact placeholder structure has a first volume and the second backside source/drain contact placeholder structure has a second volume, wherein the first volume is substantially equal to the second volume.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
a first transistor having a first channel length and comprising a first gate structure and a first source/drain region located on each side of the first gate structure;
a first backside source/drain contact placeholder structure of a first depth located beneath, and in contact with, one of the first source/drain regions of the first transistor;
a second transistor having a second channel length that is greater than the first channel length and comprising a second gate structure and a second source/drain region located on each side of the second gate structure; and
a second backside source/drain contact placeholder structure of a second depth located beneath, and in contact with, one of the second source/drain regions of the second transistor, wherein the second depth is less than the first depth.

2. The semiconductor structure of claim 1, wherein the first backside source/drain contact structure has a first backside source/drain contact placeholder structure width, and the second backside source/drain contact structure has a second backside source/drain contact placeholder structure width that is greater than the first backside source/drain contact structure width.

3. The semiconductor structure of claim 1, wherein the first backside source/drain contact placeholder structure has a first volume and the second backside source/drain contact placeholder structure has a second volume, wherein the first volume is substantially equal to the second volume.

4. The semiconductor structure of claim 1, wherein the first backside source/drain contact placeholder structure is in direct contact with the first source/drain region of the first transistor, and the second backside source/drain contact placeholder structure is in direct contact with the second source/drain region of the second transistor.

5. The semiconductor structure of claim 1, further comprising a first semiconductor buffer layer located between the first backside source/drain contact placeholder structure and the first source/drain region of the first transistor, and a second semiconductor buffer layer located between the second backside source/drain contact placeholder structure and the second source/drain region of the second transistor.

6. The semiconductor structure of claim 1, further comprising a first backside source/drain contact structure contacting the other first source/drain region of the first transistor.

7. The semiconductor structure of claim 6, further comprising a backside interconnect structure electrically connected to the first backside source/drain contact structure by a first backside power rail.

8. The semiconductor structure of claim 1, further comprising a second backside source/drain contact structure contacting the other second source/drain region of the second transistor.

9. The semiconductor structure of claim 8, further comprising a backside interconnect structure electrically connected to the second backside source/drain contact structure by a second backside power rail.

10. The semiconductor structure of claim 1, further comprising a first frontside source/drain contact structure contacting the first source/drain region that contacts the first backside source/drain contact placeholder structure, and a second frontside source/drain contact structure contacting the second source/drain region that contacts the second backside source/drain contact placeholder structure.

11. The semiconductor structure of claim 10, further comprising a frontside back-end-of-the-line (BEOL) interconnect structure contacting the first frontside source/drain contact structure and the second frontside source/drain contact structure.

12. A semiconductor structure comprising:
a first transistor having a first channel length and comprising a first gate structure and a first source/drain region located on each side of the first gate structure;
a first backside source/drain contact placeholder structure of a first depth located beneath, and in contact with, one of the first source/drain regions of the first transistor;
a second transistor having a second channel length that is greater than the first channel length and comprising a second gate structure and a second source/drain region located on each side of the second gate structure; and
a second backside source/drain contact placeholder structure of a second depth located beneath, and in contact with, one of the second source/drain regions of the second transistor, wherein the second depth is less than the first depth, the first backside source/drain contact structure has a first backside source/drain contact placeholder structure width, and the second backside source/drain contact structure has a second backside source/drain contact placeholder structure width that is greater than the first backside source/drain contact structure width, and the first backside source/drain contact placeholder structure has a first volume and the second backside source/drain contact placeholder structure has a second volume, wherein the first volume is substantially equal to the second volume.

13. The semiconductor structure of claim 12, wherein the first backside source/drain contact placeholder structure is in direct contact with the first source/drain region of the first transistor, and the second backside source/drain contact placeholder structure is in direct contact with the second source/drain region of the second transistor.

14. The semiconductor structure of claim 12, further comprising a first semiconductor buffer layer located between the first backside source/drain contact placeholder structure and the first source/drain region of the first transistor, and a second semiconductor buffer layer located between the second backside source/drain contact placeholder structure and the second source/drain region of the second transistor.

15. The semiconductor structure of claim 12, further comprising a first backside source/drain contact structure contacting the other first source/drain region of the first transistor.

16. The semiconductor structure of claim 15, further comprising a backside interconnect structure electrically connected to the first backside source/drain contact structure by a first backside power rail.

17. The semiconductor structure of claim 12, further comprising a second backside source/drain contact structure contacting the other second source/drain region of the second transistor.

18. The semiconductor structure of claim 17, further comprising a backside interconnect structure electrically connected to the second backside source/drain contact structure by a second backside power rail.

19. The semiconductor structure of claim 12, further comprising a first frontside source/drain contact structure contacting the first source/drain region that contacts the first backside source/drain contact placeholder structure, and a second frontside source/drain contact structure contacting the second source/drain region that contacts the second backside source/drain contact placeholder structure.

20. The semiconductor structure of claim 19, further comprising a frontside back-end-of-the-line (BEOL) interconnect structure contacting the first frontside source/drain contact structure and the second frontside source/drain contact structure.
